(19) United States
(12) Patent Application Publication
(10) Pub. No.: US 2019/0090341 A1
(43) Pub. Date: Mar. 21, 2019

(54) PLASMA GENERATING DEVICE

(71) Applicant: JCU CORPORATION, Tokyo (JP)

(72) Inventors: Naoki TAKAHASHI, Kanagawa (JP); Hiroyuki UEYAMA, Kanagawa (JP); Koichi NOSE, Osaka (JP)

(73) Assignee: JCU CORPORATION, Tokyo (JP)

(21) Appl. No.: 16/083,093

(22) PCT Filed: Mar. 17, 2017
(86) PCT No.: PCT/JP2017/010843

§ 371 Date: Sep. 7, 2018

(30) Foreign Application Priority Data
Mar. 17, 2016 (JP) 2016-053259

(51) Int. Cl. H05H 1/46; H01J 37/32; C23C 16/509; C23C 16/54

(52) U.S. Cl. CPC H05H 1/46; H01J 37/32449; C23C 16/54; H01J 37/32091; C23C 16/509; H01J 37/32541

(57) ABSTRACT

A plasma generating device with a pair of plate-like conductor parts each having a plurality of through-holes passing between main surfaces are opposed to each other with a predetermined gap therebetween. A gas is flowed into the through-holes from one side of the pair of plate-like conductor parts. Plasma discharge is generated in the gap by applying a high-frequency voltage between the pair of plate-like conductor parts and the generated plasma is flowed out to the other side of the pair of plate-like conductor parts.

### 1. FIELD OF THE INVENTION

This invention relates to a plasma generating device for making a prescribe plasma processing upon generating plasma.

### 2. DESCRIPTION OF RELATED ART

For manufacturing solar panels and automobile mounted lamps, plasma processing methods are employed for such as, e.g., cleaning steps, film forming steps, and etching steps because of advantages that the processing control is relatively done easily. As a plasma processing device for performing such a plasma processing method, a plasma chemical vapor deposition (CVD) apparatus has been known, which forms a thin film on a substrate upon rendering source gases plasmatic with medium frequency wave, high-frequency wave, or microwave electric power.

To form a protection film on a surface of plastic material products, a hard coating film may be formed with a thickness of one micro-meter or thicker to ensure the hardness degree and durability against scratches of the protection film. It is therefore necessary to raise a film formation rate. As one method to raise the film production efficiency, a plasma CVD apparatus utilizing hollow cathode discharge has been known (see, e.g., Patent Documents #1, #2).

### Patent Documents

Patent Document #1: Japanese Patent Application Publication No.2015-098617

Patent Document #2: Japanese Patent Application Publication No.2011-204955

Even with the plasma CVD apparatus using the hollow cathode discharge, the apparatus of a type sandwiching a substrate to be formed of a film in a space between a hollow cathodes electrode and an anode electrode, such as, e.g., the apparatus shown in Patent Document #1, tends to be readily deposited of a polymerization film at the hollow cathode electrode, thereby raising a problem not able to form a film stably due to generation of particles. Also the apparatus raises a problem that the plasma may be scattered from the interval of the electrodes to the exterior of the apparatus to lower the plasma density, make the gas profile worse, and make the film thicknesses deviated. With the apparatus, the hollow cathode electrode itself may be easily suffered from a high temperature, so that the substrate to be formed of the film may be deformed where the substrate is made of a thermoplastic resin to reduce its productivity.

Further, even with the plasma CVD apparatus using a parallel plat plate electrode pair, such as, e.g., the apparatus shown in Patent Document #2, where the one electrode is made of a silicon material, and where the electrode itself is used as a source of film formation for the method, the electrodes themselves are required to be frequently replaced in a case where the film is formed with a relatively thick thickness on the part to be formed of the film, so that such an apparatus may not be installed actually in a production line.

In consideration to solve the above problems, it is therefore an object of the invention to provide a plasma generating device generating plasma with high plasma density and producing a film with a high film formation rate.

### SUMMARY OF THE INVENTION

To solve the above technical problems, the plasma generating device according to the invention includes a pair of plate shaped conducting members, each having plural through holes penetrating between main surfaces, the conducting members facing each other via a prescribed gap. The gas is made to flow into the through holes from a side of the one conducting member, and plasma discharge is generated at the gap when a high frequency voltage is applied between the pair of plate shaped conducting members. The generated plasma flows out of the other of the plate shaped conducting members.

According to the plasma generating device, plasma is generated at a gap between the pair of the plate shaped conducting members, and the plasma generating unit and the plasma processing unit are separately structured in which the plasma generated from gas flow to the plural through holes penetrating each of the plate shaped conducting member pair flows out to the side of the other plate shaped conducting member. Accordingly, the device suppresses damages due to plasma and heat to the member to be formed of the film, thereby rendering the processing temperature relatively low. Further, according to the plasma generating device, the device can generate plasma with high density, so that the device can increase the productivity.

### BRIEF DESCRIPTION OF THE DRAWINGS

FIG. 1 is an essential perspective view showing a plasma generating device in a partly cutting way according to an embodiment of the invention;

FIG. 2 is a schematic cross sectional view showing the plasma generating device according to the embodiment of the invention;

FIG. 3 is a schematic view showing a structure of the plasma generating device according to the embodiment of the invention and illustrating a preparation stage;

FIG. 4 is a schematic view showing a structure of the plasma generating device according to the embodiment of the invention and illustrating a plasma generating stage;

FIG. 5 is a schematic view showing a structure of the plasma generating device according to the embodiment of the invention and illustrating a plasma generating stage;

FIG. 6 is a schematic view showing an example of a plasma film forming apparatus using the plasma generating device according to the embodiment of the invention;

FIG. 7 is a schematic view showing another example of a plasma film forming apparatus using the plasma generating device according to the embodiment of the invention;

FIG. 8 is a graph showing examples according to the invention;

FIG. 9 is photos illustrating the examples according to the invention; and

FIG. 10 is a diagram illustrating the examples according to the invention.

### DETAILED DESCRIPTION OF THE INVENTION

Referring to the drawings, embodiments of the invention are described. It is to be noted that the following description includes several embodiments of the invention, and this invention is not limited to those embodiments. This invention is not limited to arrangements and sizes of respective structural elements shown in the respective drawings.

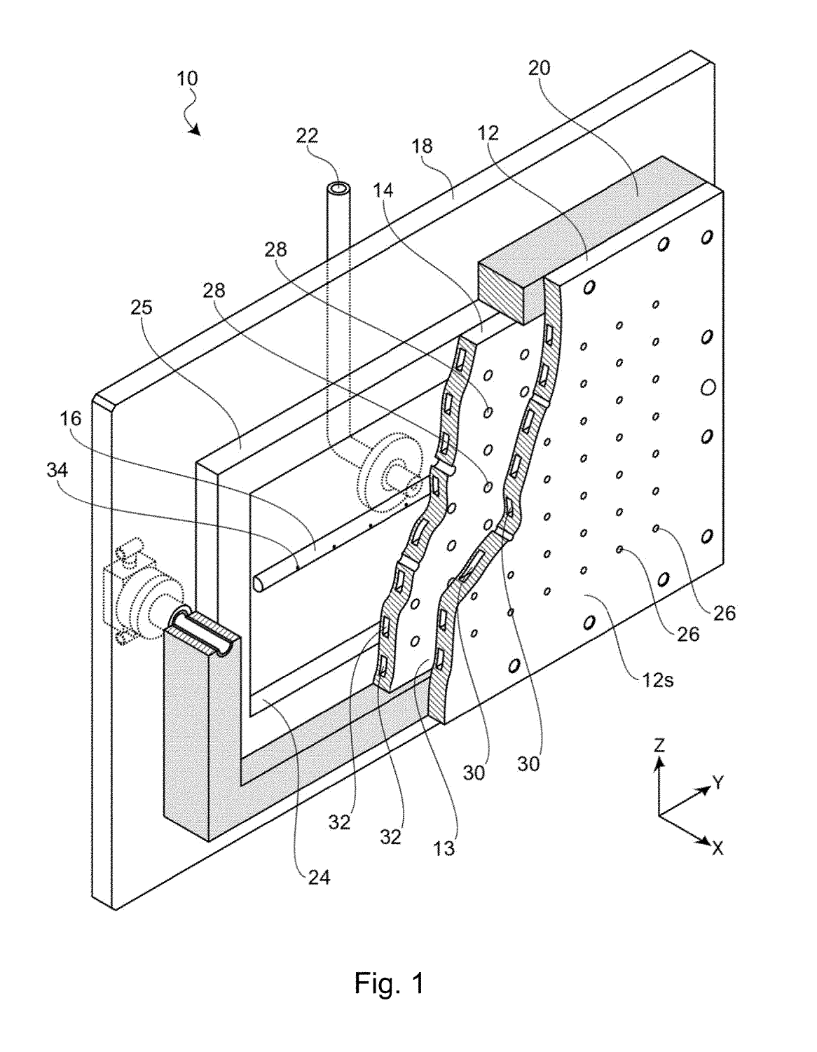

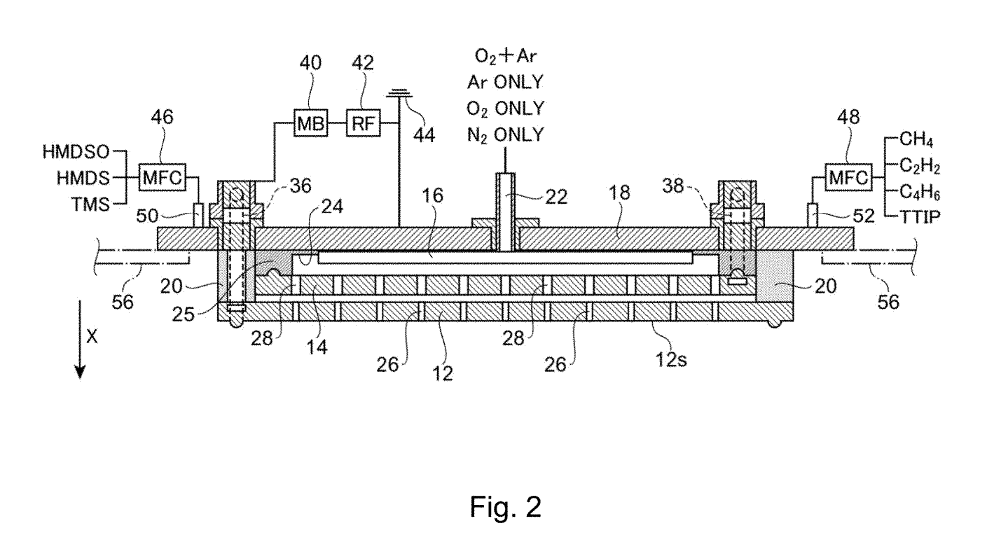

This embodiment is an example of a plasma generating device 10 for performing plasma film forming processing. As shown in FIG. 1 and FIG. 2, the plasma generating device 10 is formed with a body side member 20 on a support plate 18, and a pair of parallel plate shaped conducting members 12, 14 is formed to the body side member 20. A recess portion 24 is formed on a back surface side as one side of the pair of the parallel plate shaped conducting members 12, 14 and on an inner side of a projecting portion 25 by forming the projecting portion 25 on a surface of the support plate 18, and a plasma generating gas introduction pipe 16 is provided in extending in a horizontal direction as a longitudinal direction as arranged in the recess portion 24. A center of the plasma generating gas introduction pipe 16 is coupled to a gas supply pipe 22 extended from an exterior of the device for introducing plasma generating gas, and gas such as argon for generating plasma is introduced through the plasma generating gas introduction pipe 16 and the gas supply pipe 22.

The pair of the plate shaped conducting members 12, 14 is made of a metal plate such as plate shaped aluminum or other conducting plate, and the conducting member may include a dielectric film on the surface. A surface 12s on a plasma gas flowing-out side of the pair of the plate shaped conducting members 12, 14 may be structured in being covered with a dielectric film formed by alumina thermally spraying or hard anodizing processing to avoid such as e.g., arc discharge. Both of the main surfaces of the pair of the plate shaped conducting members 12, 14 may be furnished by alumina thermally spraying or hard anodizing processing. The pair of the plate shaped conducting members 12, 14 have the entire circumference held to or closely contacted to the body side member 20, respectively, and a gap 13 between the pair of the plate shaped conducting members 12, 14, is a space, having the same interval in a direction in the surface of the plate shaped conducting members 12, 14, surrounded by the body side member 20 and the pair of the plate shaped conducting members 12, 14. The interval between the pair of the plate shaped conducting members 12, 14 can be changed according to such as, e.g., introduced gases, frequency of the supplied electric power, sizes of the electrodes, and can be set to such as, e.g., 3 mm to 12 mm, preferably 3 mm to 9 mm, and more preferably 3 mm to 6 mm.

The pair of the parallel flat plate shaped conducting members 12, 14 is formed with plural through holes 26, 28 penetrating the two main surfaces of each member. The plate shaped conducting member 12 placed on the gas flowing-out side includes the plural through holes 26 with a prescribed interval as arranged in a matrix shape in the main surface, whereas the plate shaped conducting member 14 placed on the gas flowing-in side includes the plural through holes 28 with a prescribed interval as arranged in a matrix shape in the main surface. The through holes 26 of the plate shaped conducting members 12 and the through holes 28 of the plate shaped conducting member 14 are holes in a cylindrical shape, respectively, and the center of the through hole 26 and the center of the through hole 28 are aligned coaxially or namely in X-direction in FIG. 1. The through hole 26 of the plate shaped conducting member 12 is made having a smaller diameter than that of the through 28 of the plate shaped conducting member 14 placed on the gas flowing-in side, and therefore, where the gas flows in X-direction, the gas is accelerated more when flowing through the though hole 26 of the plate shaped conducting member 12 than when the flowing through the though hole 28 of the plate shaped conducting member 14, so that the gas flows out toward the side of the surface 12s of the plate shaped conducting member 12 with accelerated flow speed. Thus, the pair of the plate shaped conducting members 12, 14 are formed with the plural through holes 26, 28 to constitute a hollow electrode structure, so that the plasma gas generated through the plural through holes 26, 28 flows with a high density.

In this embodiment, the plural through holes 26, 28 formed in the pair of the plate shaped conducting members 12, 14 are in the cylindrical shape penetrating between the main surfaces of the plate shaped conducting members 12, 14, but can be made in a rectangular shape or in a tapered shape having a narrower diameter on the flowing out side. In this embodiment, the plural through holes 26, 28 are arranged in a matrix layout, but can be arranged in a layout having plural concentric circles, and further the positions of the plural through holes 26, 28 can be in an irregular layout. In this embodiment, it is described that the plural through holes 26 formed in the plate shaped conducting member 12 have the same diameter, respectively, whereas the plural through holes 28 formed in the plate shaped conducting member 14 have the same diameter, respectively, but can be made having the diameters changing stepwise between the center portion and the circumferential portion. The directions of the plural through holes 26, 28 may be inclined with respect to X-axis, and the directions of the through holes aligned in a concentric circle shape may be arranged in an inclined manner, thereby forming a swirl of the plasma gas.

Fluid passages 30, 32 serving as a cooling unit for passing a refrigerant such as cooling water or cooling gas and for circulating the refrigerant, are formed in the pair of the plate shaped conducting members 12, 14. The fluid passage 30 formed near a one surface of the plate shaped conducting member 12 is arranged in such as, e.g., a meander shape to pass by the vicinities of many of the through holes 26 and to function as depriving heats. The fluid passage 32 formed near a one surface of the plate shaped conducting member 14 is also arranged, in substantially the same way, in such as, e.g., a meander shape to pass by the vicinities of many of the through holes 28. The refrigerant passing through the fluid passages 30, 32 is supplied from the exterior of the device, and is returned to the fluid passages 30, 32 upon cooled again by a thermal converting apparatus not shown but provided at the exterior of the device. The fluid passages 30, 32 can be installed independently or can be installed in a connected manner In this embodiment, a groove is formed in a meander shape on a surface of an aluminum material, and the groove is covered with such as, e.g., an aluminum plate from the surface side, but the fluid passage can be drilled from a side portion side. In this embodiment, although the plate shaped conducting members 12, 14 are formed with the fluid passages 30, 32, respectively, each may be formed with plural fluid passages.

A high frequency voltage is applied to the pair of the plate shaped conducting members 12, 14 as described below, and the refrigerantflows the fluid passages 30, 32 formed in the pair of the plate shaped conducting members 12, 14 to suppress increase of the temperature of the pair of the plate shaped conducting members 12, 14. The gas for generating plasma is introduced from the plasma generating gas introduction pipe 16 described above, on the gas flowing-in side of the pair of the plate shaped conducting members 12, 14. As described above, the recess portion 24 formed in an approximately rectangular shape is formed at the support plate 18, and the recess portion 24 extends to a range over all of the through holes 28 on the back surface side of the plate shaped conducting member 14. The plasma generating gas introduction pipe 16 is arranged as to extending horizontally as in the longitudinal direction in a space formed from the recess portion 24 and the back surface of the plate shaped conducting member 14, and the plasma generating gas is introduced from plural holes 34 provided in a scattered manner along the longitudinal direction of the plasma generating gas introduction pipe 16 into the space formed from the recess portion 24 and the back surface of the plate shaped conducting member 14. The plasma generating gas introduction pipe 16 is a single pipe shaped member, and because the pipe is coupled to the gas supply pipe 22 in a letter-T shape at a center portion in the longitudinal direction, the gas supplied from the gas supply pipe 22 is introduced into the recess portion 24 through the plasma generating gas introduction pipe 16. The plasma generating gas is selected according to the method for processing with plasma, and is such as, e.g., argon gas, mixture gas of argon and oxygen gases, either oxygen or nitrogen, and further may be helium, carbon dioxide, nitrous oxide, hydrogen, air, and mixture gas of those.

The body side member 20 is a member formed in a projecting manner toward the device surface side from the support plate 18, and holds the entire end of the plate shaped conducting member 12. The body side member 20 at the surface thereof is attached as putting a lid in closely contacting the end of the surface of the body side member 20 with the back surface of the plate shaped conducting members 12. The body side member 20 makes air-tight a space formed between the recess portion 24 formed inside a projecting portion 25 and the back surface of the plate shaped conducting member 14, as well as a space between the pair of the plate shaped conducting members 12, 14, respectively, except the plasma generating gas introduction pipe 16 and the through holes 26, 28 of the gas. The body side member 20 is formed of an insulating material such as, e.g., glass, and ceramics. As shown in FIG. 2, the body side member 20 is formed with a fluid passage pipe 36 supplying the refrigerant to the plate shaped conducting member 12 on the flowing-out side, and the fluid passage pipe 36 is in communication with the fluid passage 30 formed inside the plate shaped conducting member 12 from the back surface side of the plate shaped conducting member 12 in penetrating the body side member 20 in the X-axis direction. The other of the fluid passage pipe 36 is in communication with the exterior of the device in penetrating the support plate 18. When the fluid passage pipe 36 penetrates the support plate 18, the pipe also penetrates the body side member 20 made of the insulating material arranged at the support plate 18, so that the support plate 18 is maintained to be electrically insulated with the fluid passage pipe 38. The plate shaped conducting member 14 is formed with a fluid passage pipe 38 attached to the inside of the body side member 20, and the fluid passage pipe 38 is in communication with the exterior of the device in penetrating the support plate 18. The pair of the plate shaped conducting members 12, 14 can be prevented from increasing their temperatures by passing the refrigerant such as, e.g., cooling water through those fluid passage pipes 36, 38.

Those fluid passage pipes 36, 38 serve as pipes supplying the refrigerant and are made of a conducting body, so that the pipes 36, 38 function as electrode plugging portions for the parallel flat plate shaped conducting members 12, 14. The gap 13 exists between the parallel flat plate shaped conducting members 12, 14, and the gap 13 functions dielectric portion of a capacitor. As shown in FIG. 2, one end of a high frequency power supply (RF) 42 is connected to the ground 44; the support plate 18 is connected to the ground; and the plate shaped conducting member 14 on the back surface side is also connected to the ground via the fluid passage pipe 38 penetrating the support plate 18 with no insulator between the pipe and the plate. The other end of the high frequency power supply 42 is connected to the fluid passage pipe 36 via a matching box (MB) 40 for obtaining consistency to the plasma by manipulating capacitance and the like. The fluid passage pipe 36 penetrates the support plate 18 as electrically isolated from the support plate 18, and is electrically connected to the pair of the plate shaped conducting member 12 on the surface side. When the high frequency power supply 42 is turned on, the potential of the plate shaped conducting member 12 is therefore alternated between plus and minus with a prescribed frequency such as, e.g., 13.56 MHz.

Ports 50, 52 for flowing the film forming gas inside are attached on a side of the support plate 18, and the film forming gas is supplied via mass flow controllers (MFC) 46, 48 having a mass flow meter with function of flow amount control. In this embodiment, the introduction portion of the film forming gas is set to the side portion the support plate 18 as an example, and other structures may be employed if having a mechanism supplying the film forming gas to a vicinity of the product processed with plasma. If this plasma generating device is used for cleaning using plasma, the mass flow controllers 46, 48 may stop the film forming gas to flow in. The film forming gas may be supplied upon being selected from such as, e.g., methane, acetylene, butadiene, titanium tetraisopropoxide (TTIP), hexamethyldisiloxane (HMDSO), hexamethyldisilazane (HMDS), and tetoramethylsilane, (TMS),

The support plate 18 itself can be attached to such as, e.g., a chamber 56 of a plasma film forming apparatus, and the film forming gas introduced via the ports 50, 52 is introduced into the chamber of the plasma film forming apparatus as described below. Where the plasma generating device 10 is attached to the chamber of the film forming apparatus, the interior of the chamber is made to be relatively low vacuum, for example, approximately from 10 to 300 pascal, by vacuum evacuation, not shown, in the chamber. The plasma is generated under this state by energization to promote plasma processing such as film formation and cleaning with the generated plasma.

An example of sizes of an essential portion of the plasma generating device producing the plasma with high density and generating the plasma stably is described herein. First, with respect to the space of a volume V₁ sandwiched by the recess portion 24 and the back surface of the plate shaped conducting member 14, obtained experimental consequences are that it is effective to form a thickness of the space is 3 mm to 20 mm, preferably, 5 mm to 12 mm to increase efficiency. Where the plate thickness of the plate shaped conducting member 14 is set to ti and the diameter of the through hole 28 is set to d₁, and where the number of the through holes is set to A, d₁ is equal to or less than 2t₁, and At₁ π (d₁)²/4 is preferably a value from the space V₁/120 cm³ to V₁/80 cm³, and more preferably a value from the space V₁/110 cm³ to V₁/90 cm³. Next, with respect to a volume V₂ of the gap 13 between the plate shaped conducting members 12, 14, obtained experimental consequences are that it is effective to form a thickness of the gap is 2 mm to 12 mm, preferably, 3 mm to 6 mm to increase efficiency. Where the plate thickness of the plate shaped conducting member 12 is set to t₂ and the diameter of the through hole 26 is set to d₂, and where the number of the through holes 26 is set to A, d₂ is equal to or less than 2t₂, and At₂ π (d₂)²/4 is preferably a value from the space V₂/120 cm³ to V₂/80 cm³, and more preferably a value from the space V₂/110 cm³ to V₂/90 cm³. It is to be noted that the through holes 26 and the through holes 28 are placed coaxially, the number A of each is the same.

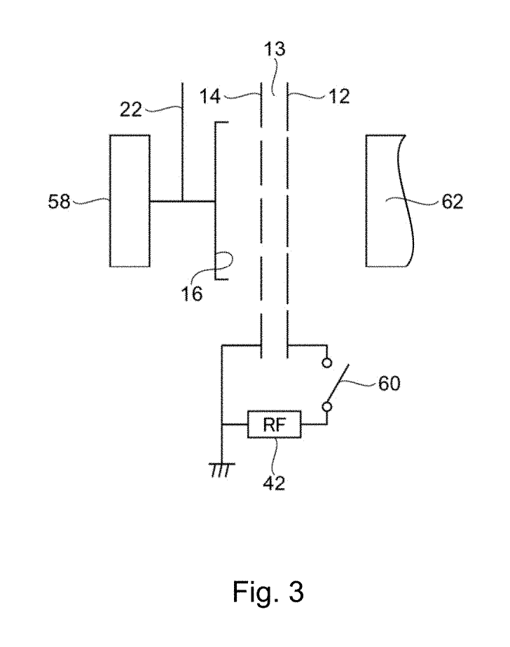

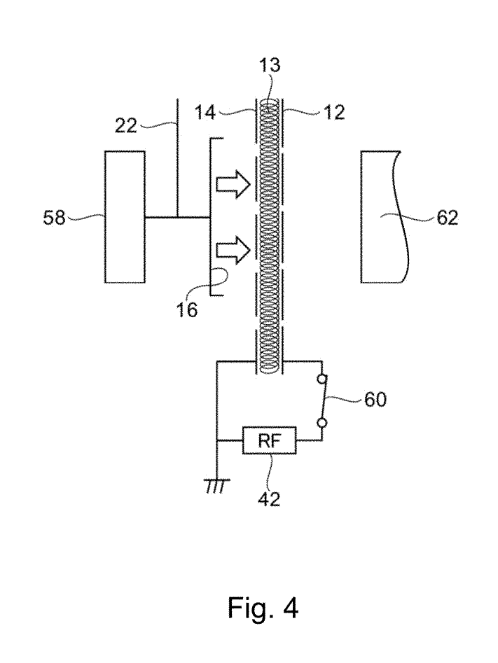

FIG. 3 to FIG. 5 are schematic views illustrating the operation of the plasma generating device 10 of this embodiment. FIG. 3 shows a preparation stage, and on the circuit, the pair of the parallel plate shaped conducting members 12, 14 constitutes counter electrodes facing each other, and one end of the high frequency power source 42 is connected to the ground whereas the other end is connected to the plate shaped conducting member 12 via a switch 60. The parallel plate shaped conducting member 14 is also connected to the ground in substantially the same way as the one end of the high frequency power source 42. The plasma generating gas supply apparatus 58 is connected to the plasma generating gas introduction pipe 16 via the flow amount controller, not shown. In this preparation stage, the plasma generating device 10 is set to a low vacuum state of, e.g., 10 to 300 pascal upon operation of the vacuum pump or the like, and a work piece 62 is loaded on a front surface side of the parallel plate shaped conducting memberl2.

Where the switch 60 is turned on as shown in FIG. 4 under this stage, the gap 13 between the parallel plate shaped conducting members 12, 14 is rendered in a high frequency discharge state, and at the same time, a plasma generating gas such as a mixture gas of oxygen and argon from the plasma generating gas supply apparatus 58 is introduced into the gap 13 between the parallel plate shaped conducting members 12, 14 via the plasma generating gas introduction pipe 16. Consequently, the plasma is generated at the gap 13 between the plate shaped conducting members 12, 14.

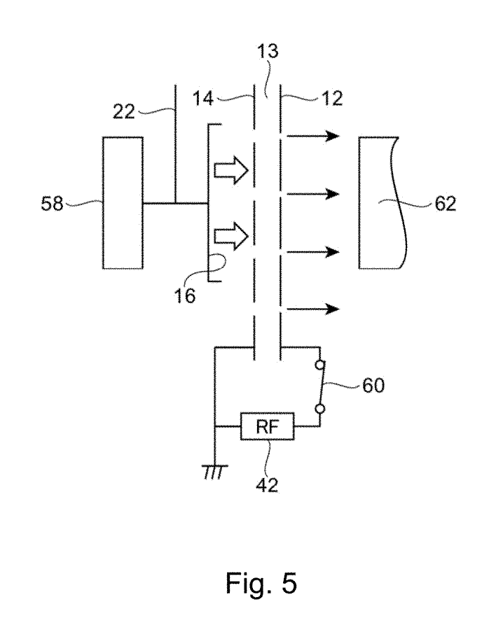

Concurrently with generation of the plasma at the gap 13 between the plate shaped conducting members 12, 14, the gas is continuously supplied from the plasma generating gas supply apparatus 58, and as a result, the generated plasma is fed from the gap 13 between the plate shaped conducting members 12, 14 to the surface side of the plate shaped conducting member 12. Because the through hole 28 has a larger diameter on the plate shaped conducting member 14 on the back surface side and because the through hole 26 has a smaller diameter on the plate shaped conducting member 12 on the front surface side, the plasma gas flows out relatively at a high rate from the surface of the plate shaped conducting member 12 on the front surface side, as shown in FIG. 5. By flowing the film forming gas to the flown-out plasma gas at a vicinity of the work piece 62, film formation can be done with excellent effectiveness. The chamber in which the plasma generating device 10 is provided, is in a state of a high pressure in comparison with a conventional sputtering method, as described above, and under such a pressure, high energy particles tend to lose their kinetic energy according to collisions with argons, so that the film formed on the surface of the work piece 62 receives less damages. The growth rate also can be made faster.

It is be noted that the plasma generating device 10 can make a prescribed film forming process by flowing the film forming gas, and also can make other applications of the plasma gas. For example, the plasma generating device 10 can be used for etching and cleaning, and further surface modification such as surface oxidizing or nitrizing.

As described above, the fluid pipes 36, 38 functioning as a cooling unit are formed inside the pair of the plate shaped conducting members 12, 14, and where the refrigerant such as, e.g., a cooling water is made to pass the fluid pipes 36, 38, the pair of the plate shaped conducting members 12, 14 can be prevented from increasing their temperature. The plasma generating device 10 of this embodiment, at a stage of a prescribed film formation, can reduce the film formation on a side of the plate shaped conducting members 12, 14, can increase the formation rate of the film on a side of the work piece 62, and can form the film with a thick thickness in a relatively short time.

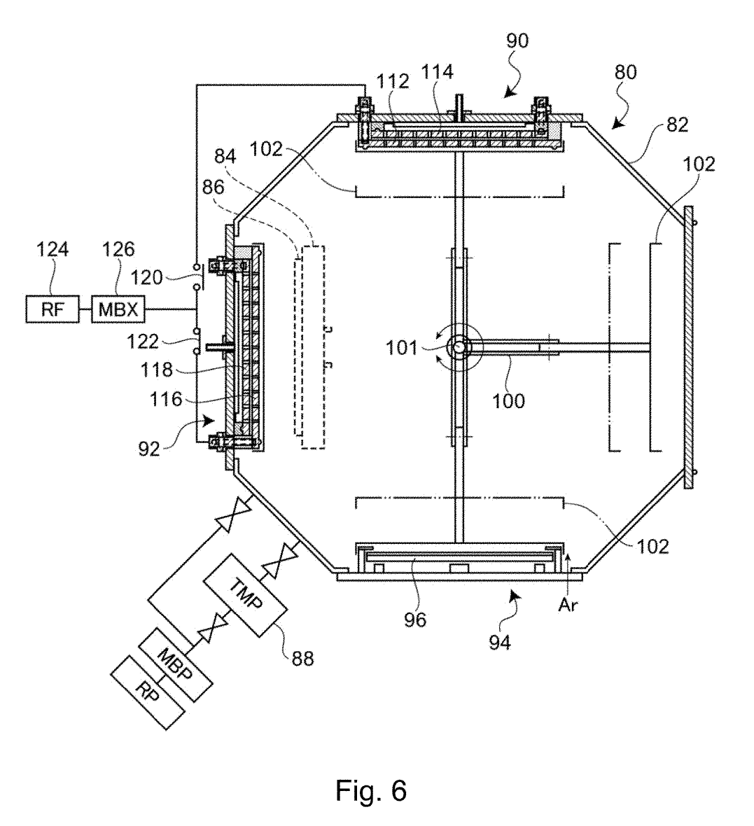

FIG. 6 is a schematic diagram showing an example of a plasma film forming apparatus using the plasma generating device of the embodiment. The plasma film forming apparatus 80 is structured of plasma generating devices 90, 92, as described above, provided in a chamber 82, and a sputtering apparatus 94 for film forming in the same chamber 82. The plasma generating device 90, the plasma generating device 92, and the sputtering apparatus 94 are arranged adjacent to each other on side walls of four directions of approximately an octagon as a horizontal cross section, and remaining side walls are used as loading opening for work pieces.

The plasma generating device 90 and the plasma generating device 92 have a structure generating plasma at a gap between the pair of parallel plate shaped conducting members 112, 114 and at a gap between the pair of parallel plate shaped conducting members 116, 118, performing plasma processing on a wok piece 82 on a support base 84 shown by a broken line in FIG. 6. High frequency electric power from a high frequency power source 124 via a matching box 126 is selectively supplied to the plasma generating devices 90, 92 via selection switches 120, 121, respectively. Argon gas is supplied to a surrounding of the sputtering apparatus 94, and the sputtering apparatus 94 has a structure in which a target material from a target 96 supplied with a direct current voltage is deposited on the facing work piece 86.

The plasma film forming apparatus 80 of this structure has an arm unit 100 extending in three directions from a center of the chamber 82, and the arm unit 100 moves pivotally around an axial portion 101. A shutter 102 is attached to a tip of the arm unit 100 extending in the three directions, and the shutter 102 and the arm unit 100 constitute a shutter mechanism. With this shutter mechanism, the plasma generating devices 90, 92, and the sputtering apparatus 94 are connected and disconnected in accordance with extension and contraction of the arm unit 100, so that the plasma generating devices 90, 92, and the sputtering apparatus 94 are selectively connected to the interior of the chamber 82.

It is to be noted that the chamber 82 in the plasma generating device 80 is attached with a prescribed exhaust unit 88, and can make the interior of the chamber 82 low vacuum.

The plasma generating device 80 can operate with good productivity when forming a metal film relatively thick, particularly, on the surface of a resin material. That is, where a metal thin film is formed on a resin material by plating, the work piece 86 made of, e.g., a resin material on the support base 84 is processed in a counterclockwise direction among the plasma generating devices 90, 92, and the sputtering apparatus 94. First, the plasma generating device 90 is used as a plasma cleaning device, and the work piece 86 is cleaned or modified with the plasma by rendering the work piece 86 facing the plasma generating device 90. Subsequently, the arm unit 100 is turned around 90 degrees in the counterclockwise direction, the work piece 86 is formed with a thin metal catalyst layer or added with functional groups, from a prescribed polymerization action. In the sputtering apparatus 94, a seed layer such as nickel is formed on the work piece 86 by sputtering. Sputtering may be possible without using any of the plasma generating devices 90, 92, but if cleaning or modification in use of plasma, formation of a metal thin catalyst layer, or addition of functional groups is made using the plasma generating devices 90, 92 before sputtering, the film formed in a post process step can be formed with very high adhering force as obtained from experiments.

It is to be noted that the plasma film forming apparatus 80 is described as an apparatus installing the sputtering apparatus 94, it is also possible to install a single or plural plasma CVD apparatuses, and it is also possible to install a vaporizing apparatus in lieu of the sputtering apparatus 94. The plasma generating device is also useful for etching processing.

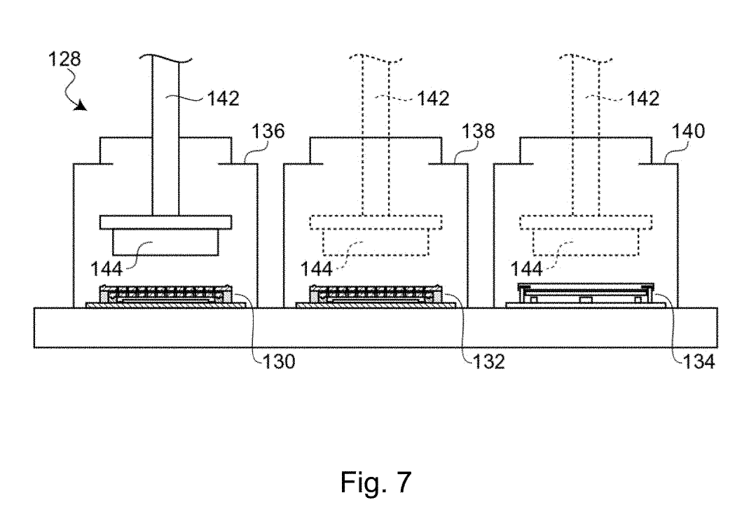

FIG. 7 is a schematic view showing another example of a plasma film forming apparatus 128 using the plasma generating device according to the embodiment. The plasma film forming apparatus 128 has a structure including three chambers 136, 138, 140, and provides the plasma generating devices 130, 132 as described above in the chambers 136, 138, respectively, and provides a sputtering apparatus 134 for film forming in the chamber 140 next to the chambers. In the first chamber 136, a work piece 144 attached to a tip of a support arm 142 faces the plasma generating device 130 to make plasma cleaning. The work piece 144 then moves together with the support arm 142, and in the subsequent chamber 138, the plasma generating device 132 makes the plasma processing, thereby forming a thin metal catalyst layer from the prescribed polymerization action or attaching functional groups to the work piece 144. In the third chamber 140, the seed layer such as, e.g., nickel is formed on the work piece 144 by sputtering.

With the structure having independent chambers, the plasma does cleaning and modifying, as well as forming of the thin metal catalyst layer and adding the functional groups according to the plasma film forming apparatus 128 using the plasma generating device, so that the film formed in a post process step can be formed with very high adhering force. A combination is possible in which the plasma generating devices 130, 132 are arranged in the same chamber whereas the sputtering apparatus is installed in another chamber.

It is to be noted that in the above embodiment, the electric power source supplied to the pair of the parallel plate shaped conducting members is described as a high frequency power source, but an alternative current power source and a pulse direct current power source can be used in lieu of the high frequency power source.

Experiment 1: Status Confirmation after Substrate Surface Modification

A surface modification of an ABS material was made using the plasma generating device according to this embodiment, and the material surface after modification was evaluated using XPS (X-ray Photoelectron Spectroscopy) and SEM (Scanning Electron Microscope).

### Plasma Processing Step

An ABS material was set in the apparatus chamber, and after the pressure of the chamber was reduced to a prescribed pressure, oxygen gas was supplied, and a prescribed high frequency voltage was given to the counter electrodes made of the plate shaped conducting members. The material surface was modified by radiating the generated plasma to the ABS material surface. The plasma processing condition is shown in Table 1. In Table 1, T-S interval (mm) indicates the distance between the electrode and the material.

TABLE 1

| | Plasma Processing Condition | | | | | | |
|---|---|---|---|---|---|---|---|
| | | Applied | | Electric | | | |
| | T-S | electric | Discharge | power | O₂ | | Process |
| | Interval | power | unit area | density | amount | Pressure | time |
| | (mm) | (W) | (cm²) | (W/cm²) | (sccm) | (Pa) | (sec) |
| Non-Processing | — | — | — | — | — | — | — |
| Processing 1 | 200 | 1300 | 114.6 | 11.34 | 1500 | 18 | 120 |
| Processing 2 | 200 | 1800 | 114.6 | 15.71 | 1500 | 18 | 120 |
| Processing 3 | 100 | 800 | 114.6 | 6.98 | 1500 | 18 | 120 |
| Processing 4 | 50 | 800 | 114.6 | 6.98 | 1500 | 18 | 120 |
| Processing 5 | 50 | 1500 | 114.6 | 13.09 | 1500 | 18 | 120 |

| | XPS analysis result | | |
|---|---|---|---|
| | C1S | N1S | O1S |
| Non-Processing | 89.8 | 5.1 | 4.2 |
| Processing 1 | 73.5 | 4.1 | 20.9 |
| Processing 2 | 66.7 | 3.7 | 26.7 |
| Processing 3 | 69.3 | 4.1 | 23.1 |
| Processing 4 | 66.8 | 2.6 | 24.8 |
| Processing 5 | 62.2 | 2.8 | 27.7 |

### Confirmation by XPS

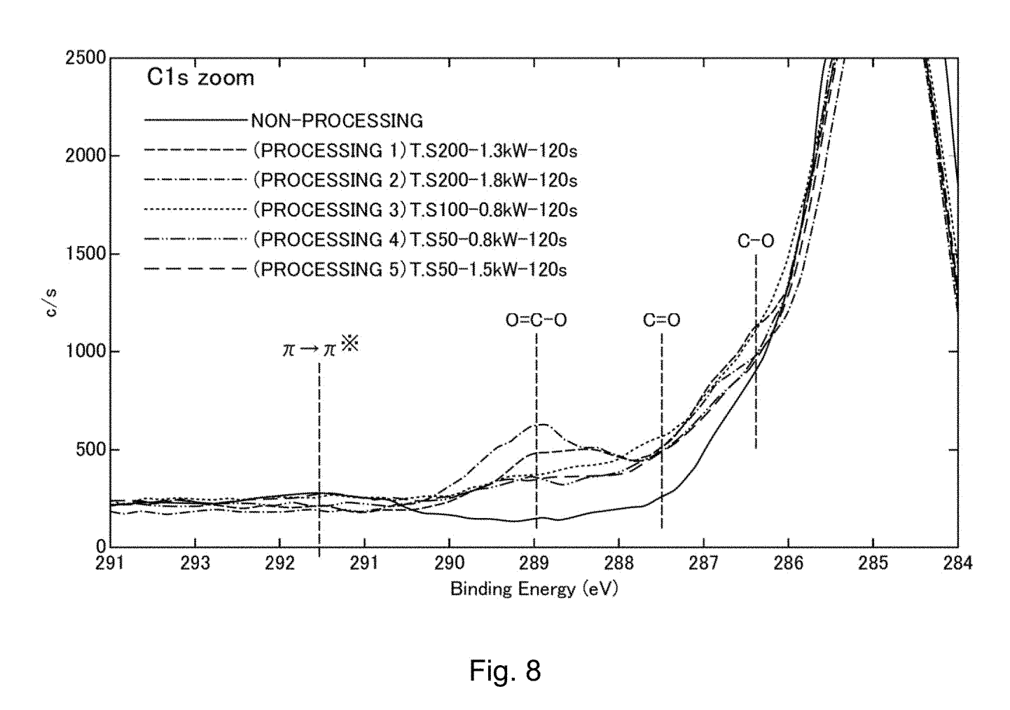

The surfaces of the ABS materials, to which respective processings shown as Processing 1 through Processing 5 were made, and the non-processing ABS material surface were analyzed using the XPS, and chemical banding state on the material surface was observed from energy shift (amount) of the photoelectron peak position. FIG. 8 is a graph showing the chemical binding state on the material surface of each processing obtained from the XPS analysis; the vertical axis shows photoelectron intensity; and horizontal axis shows binding energy. As apparent from FIG. 8, on the ABS material surfaces processed with Processing 1 to Processing 5, the photoelectron peak particular to the carboxyl group around 289 eV was observed, and it was confirmed that the modification of the ABS material surfaces was done by the plasma generating device of the embodiment.

### Confirmation by SEM

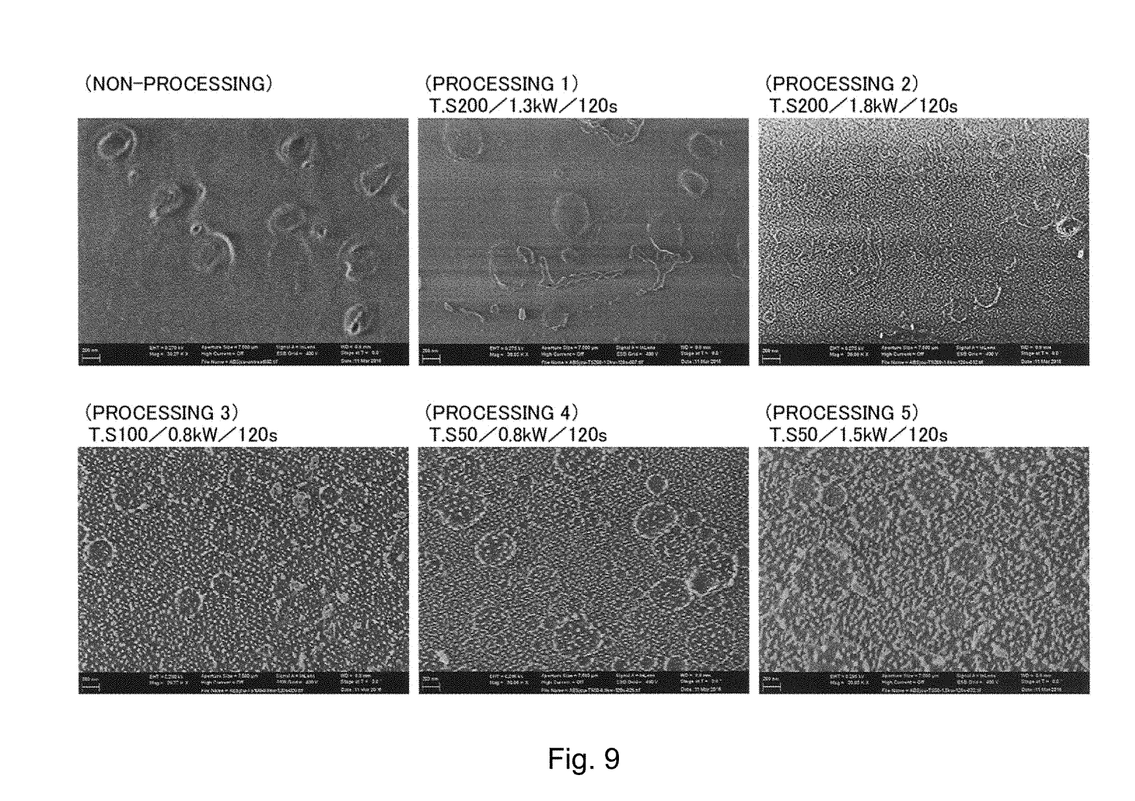

The surfaces of the ABS materials, to which respective processings shown as Processing 1 through Processing 5 were made, and the non-processing ABS material surface, were observed by SEM in substantially the same manner as the XPS measurement. FIG. 9 is a microscopic observation image of the ABS material surfaces obtained from the SEM observation. From the observation results of the ABS material surfaces to which Processing 1 to Processing 5 were made, it was confirmed that the ABS material surfaces were etched in a scale of nano meters.

Experiment 2: Confirmation on Adhesive Improvement after Modification of the Material Surfaces

The surfaces of the ABS material and the PC/ABS material were modified using the plasma generating device according to the embodiment, and after a copper plating film was formed, a peeling strength test was performed.

### Plasma Processing Step

The ABS material and the PC/ABS material were set in the apparatus chamber, and after the pressure of the chamber was reduced to a prescribed pressure, where oxygen gas was supplied in a certain amount, a prescribed high frequency voltage was applied to counter electrodes made of the plate shaped conducting members. The generated plasma was radiated to the surfaces of the ABS material and the PC/ABS material to modify the material surfaces. The plasma processing conditions are summarized in Table 2. It is to be noted that T-S interval (mm) in Table 2 indicates the distance between the electrode and the material.

TABLE 2

| | Plasma Processing Condition | | | | | | |
|---|---|---|---|---|---|---|---|
| | | Applied | | Electric | | | |
| | T-S | electric | Discharge | power | O₂ | | Process |
| | Interval | power | unit area | density | amount | Pressure | time |
| Material Name | (mm) | (W) | (cm²) | (W/cm²) | (sccm) | (Pa) | (sec) |
| ABS | 100 | 500 | 16.59 | 30.14 | 1000 | 10 | 240 |
| PC/ABS | 100 | 500 | 16.59 | 30.14 | 1000 | 10 | 240 |

| Material Name | Peel strength (kg/cm) |
|---|---|
| ABS | 1.87 |
| PC/ABS | 0.8 |

### Seed Layer Film Formation Step

The material of the post surface modification was set in the chamber of the sputter apparatus, and after the pressure of the chamber was reduced to a prescribed pressure, where argon gas was supplied in a certain amount, a direct current voltage was applied to the copper target, thereby forming a copper seed layer having a thickness of about 400 nm on the material surface.

### Electroplating Step

The material of the post copper seed layer formation was attached to a plating jig, and was dipped in a copper sulfate plating bath for ornament together with a copper anode. Where the anode was set o the copper anode while the cathode was set to the work piece, and where a direct current voltage was given, a copper plating film having a thickness of around 32 microns was formed.

### Confirmation of Adhesion Characteristics

After the copper plating film was formed on the ABS material and the PC/ABS material according to the above three steps, the 90 degree peel strength test was performed using a tension tester (made of Shimazu Corporation; AGS-H500N). As indicated in the column of the Peel strength on a lower side in Table 2, it was confirmed that both of the ABS material and the PC/ABS material were adhered strongly.

### Experiment 3: Confirmation on Abrasion Resistance

Using the plasma generating device according to the embodiment, a material surface on which the color ring (having an optical interference film thickness: about 300 nm) on an SUS304 material was formed, was modified, and abrasion resistance test was performed after SiOx film was firmed.

The material was set in the apparatus chamber, and after the pressure of the chamber was reduced to a prescribed pressure, where the hexamethyldisilazane (HMDS) and oxygen gas was supplied in a certain amount, a prescribed high frequency voltage was applied to counter electrodes made of the plate shaped conducting members. A transparent SiOx film was formed at a film formation rate of 3 nm/sec by CVD. The plasma processing conditions are summarized in Table 3. It is to be noted that T-S interval (mm) in Table 3 indicates the distance between the electrode and the material.

TABLE 3

| | Plasma Processing Condition | | | | | | |
|---|---|---|---|---|---|---|---|
| | | Applied | | Electric | | | |
| | T-S | electric | Discharge | power | O₂ | | Process |
| SiOx film | Interval | power | unit area | density | amount | Pressure | time |
| Thickness | (mm) | (W) | (cm²) | (W/cm²) | (sccm) | (Pa) | (sec) |
| 3 μm | 250 | 1000 | 114.6 | 8.73 | 1200 | 8 | 1000 |
| 6 μm | 250 | 1000 | 114.6 | 8.73 | 1200 | 8 | 2000 |
| 9 μm | 250 | 1000 | 114.6 | 8.73 | 1200 | 8 | 3000 |

### Comfirmation on Adhesion Characteristics

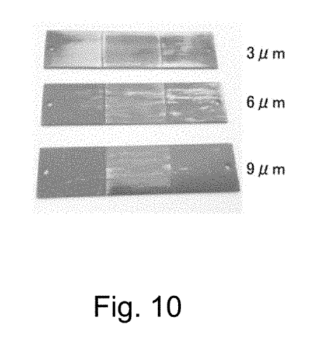

As shown in Table 3, a sand eraser (made of SEED Co.,Ltd: E-512) was pushed with a pressure of 1 kgf to the material surface on which the SiOx film was formed by the above processing steps in having the thickness of 3 micron meters, 6 micron meters, and 9 micron meters, respectively, and the results of 150 times reciprocal movements were shown in FIG. 10. As shown in FIG. 10, where the thickness was 3 micron meters, the optical interference film was peeled for nearly a half with respect to the material surface area, but as the thickness was made thicker such as 6 micron meters and 9 micron meters, the optical interference film was peeled less, and it was confirmed that the scratch feature became improved.

As described above, according to the plasma generating device of the invention, the plasma generating unit and the plasma processing unit are structured as separated. Accordingly, it is particularly useful to avoid damages due to plasma's heat to the work piece, and because high density plasma can be generated, it is suitable to increase productivity.

1-13. (canceled)

14. A plasma generating device comprising:
a pair of plate shaped conducting members, each having plural through holes penetrating between main surfaces, the conducting members facing each other via a prescribed gap to form a hollow electrode structure;
one of the plate shaped conducting members rendering gas flow into the through holes from a side of the one of the conducting members;
the pair of plate shaped conducting members, upon application of a high frequency voltage between the conducting members, to generate plasma discharge at the gap; and
the other of the plate shaped conducting members rendering the generated plasma flow out,
wherein the plasma discharge is performed in a vacuum of 8 to 300 Pa.

15. The plasma generating device according to claim 14, wherein the pair of the plate shaped conducting members are so arranged that the plate shaped main surfaces face each other in parallel with an equal interval.

16. The plasma generating device according to claim 15, wherein the gap between the pair of the plate shaped conducting members is formed by separation of around 3 to 12 mm

17. The plasma generating device according to claim 14, wherein the plural through holes formed in the pair of the plate shaped conducting members are aligned to have the same axis between the one and the other of the plate shaped conducting members.

18. The plasma generating device according to claim 14, wherein each of the through holes has a cylindrical shape, and the through hole on a gas flowing-into side of the pair of the plate shaped conducting members has a diameter larger than the through hole on a gas flowing-out side of the pair of the plate shaped conducting members.

19. The plasma generating device according to claim 14, wherein the pair of the plate shaped conducting members includes a cooling unit for cooling the plate shaped conducting members.

20. The plasma generating device according to claim 14, wherein the cooling unit is made of a fluid passage formed in the pair of the plate shaped conducting members for circulating a refrigerant supplied from an exterior of the device.

21. The plasma generating device according to claim 14, wherein the surface of the pair of the plate shaped conducting members on a gas flowing-out side is formed with a dielectric film covering the surface.

22. The plasma generating device according to claim 14, wherein the dielectric film is formed from thermally spraying alumina or from hard anodizing processing.

23. A plasma film forming apparatus comprising:
a pair of plate shaped conducting members, each having through holes penetrating between main surfaces of the member, facing each other via a prescribed gap to form a hollow electrode structure;
a gas flowing-in unit for flowing gas into the through holes from a one side of the pair of the plate shaped conducting members;
a high frequency generating unit applying a high frequency voltage between the pair of the plate shaped conducting members; and
a source gas supplying unit for supplying a source gas to a plasma flown out on the other side of the pair of the plate shaped conducting members,
wherein the plasma discharge made by application of the high frequency voltage is performed in a vacuum of 8 to 300 Pa.

24. A plasma film forming apparatus comprising:
the plasma generating device as set forth in claim 14 arranged in a chamber; and
a sputtering apparatus for forming a film arranged in the same chamber.

25. A plasma film forming apparatus comprising:
at least two chambers, one chamber having the plasma generating device as set forth in claim 14 arranged therein and the other chamber having a sputtering apparatus for forming a film arranged therein.

26. A plasma film forming apparatus comprising:
the plasma generating device as set forth in claim 14 arranged to face plural chambers;
a sputtering apparatus for forming a film arranged to face the same chambers; and
a shutter mechanism for connecting and disconnecting the plasma generating device and the sputtering apparatus,
wherein the shutter mechanism selectively connects the chamber with the plasma generating device and the sputtering apparatus.
